(19) United States
(12) Patent Application Publication
(10) Pub. No.: US 2025/0113472 A1
(43) Pub. Date: Apr. 3, 2025

(54) Electrostatic Grounding Structures

(71) Applicant: APPLE INC., Cupertino, CA (US)

(72) Inventors: Shaowu Huang, Los Altos, CA (US); Jing Li Lim, Sunnyvale, CA (US); Keong W. Kam, San Jose, CA (US); Michael J. Woods, Sunnyvale, CA (US); Ramachandran Chundru, Cupertino, CA (US); Jan K. Quijalvo, San Jose, CA (US); Martin R. Kardasz, Mountain View, CA (US)

(21) Appl. No.: 18/806,212

(22) Filed: Aug. 15, 2024

Related U.S. Application Data
(60) Provisional application No. 63/540,948, filed on Sep. 28, 2023.

(51) Int. Cl. H05K 9/00; G06F 1/16

(52) U.S. Cl. CPC H05K 9/0054; G06F 1/163; H05K 9/006

(57) ABSTRACT

A head-mounted device includes a connector that electrically connects a first component to a second component. A first low impedance path is provided from the connector to the first component. A second low impedance path is provided from the first component to the second component. The first low impedance path and the second low impedance path reduce the likelihood and/or severity of electrostatic discharge events and/or electrostatic coupling that may affect the head-mounted device.

### CROSS-REFERENCE TO RELATED APPLICATIONS

This application claims priority to U.S. Provisional Application Ser. No. 63/540,948, filed Sep. 28, 2023, the contents of which are incorporated herein by reference.

### FIELD

The present disclosure relates generally to the field of electrical grounding for electronic devices.

### BACKGROUND

Electronic devices may include components that are sensitive to electrostatic charge. Electrostatic charge may cause electrostatic discharge events or electrostatic coupling. An electrostatic discharge event may occur when a difference between electrostatic potentials (voltage potential) of two objects (e.g., a user of the electronic device and a component of the electronic device or two components of the electronic device) exceeds a threshold, causing the electrostatic charge to be rapidly transferred between the two objects. Electrostatic coupling causes energy from one circuit to be transferred to another circuit through an electrostatic field.

### SUMMARY

One aspect of the disclosure is a head-mounted device that includes a frame, an optical module that is connected to the frame, and a control board that is connected to the frame. The optical module is configured to display content to a user wearing the head-mounted device. The head-mounted device also includes a flexible cable and a grounding member that is located on an exterior surface of the flexible cable. The flexible cable has a first end and a second end and is electrically connected to the control board and to the optical module. The grounding member directs an electrical charge away from the flexible cable, the optical module, and the control board. The head-mounted device also includes an antenna that is configured to receive other signals from a source. The antenna includes a grounding path that is in conductive communication with the grounding member and the frame to direct the electrical charge from the grounding member to the frame through the antenna grounding path.

Another aspect of the disclosure is a head-mounted device that includes a frame, an optical module that is connected to the frame, and a control board that is connected to the frame. The optical module is configured to display content to a user waring the head-mounted device. The head-mounted device also includes a flexible cable and a grounding tab that is in contact with an exterior surface of the flexible cable adjacent to the first end of the flexible cable. The flexible cable has a first end and a second and is electrically connected to the control board at the first end and is electrically connected to the optical module at the second end. The grounding tab electrically connects (couples) the flexible cable to the frame and defines a low impedance path from the exterior surface of the flexible cable to the frame.

Another aspect of the disclosure is a head-mounted device that includes a frame, an optical module connected to the frame, and a control board that is connected to the frame. The optical module is configured to display content to a user wearing the head-mounted device. The head-mounted device also includes a flexible cable and a conductive gasket that is in contact with an exterior of the flexible cable adjacent to the first end of the flexible cable to define a first low impedance path from the flexible cable to ta grounding path of the control board. The head-mounted device also includes a grounding member that defines a second low impedance path from the grounding path of the control board to the frame.

Another aspect of the disclosure is a head-mounted device that includes a frame, an optical module that is movably connected to the frame, and a control board that is fixedly connected to the frame. The optical module is configured to display content to a user wearing the head-mounted device. The optical module includes an optical module connector and the control board includes a control board connector. The head-mounted device also includes a flexible electrical connector that is electrically coupled to the optical module connector and to the control board connector, and is configured to transmit a signal between the optical module and the control board. The head-mounted device also includes a grounding cable that is configured to direct an electrical charge to the frame, wherein the grounding cable includes a non-insulated conductor that extends along a portion of the flexible electrical connector.

### BRIEF DESCRIPTION OF THE DRAWINGS

FIG. 1 is a front view illustration of a head-mounted device.

FIG. 2 is a top view illustration of the head-mounted device of FIG. 1.

FIG. 3 is a partial cross-sectional view illustration of the head-mounted device of FIG. 2 taken along line A-A.

FIG. 4 is a partial cross-sectional view illustration of the head-mounted device of FIG. 1 taken along line B-B and including a grounding configuration according to a first example.

FIG. 5 is a partial cross-sectional view illustration of the head-mounted device of FIG. 1 taken along line B-B and including a grounding configuration according to a second example.

FIG. 6 is a partial cross-sectional view illustration of the head-mounted device of FIG. 1 taken along line B-B and including a grounding configuration according to a third example.

FIG. 7 is a partial cross-sectional view illustration of the head-mounted device of FIG. 1 taken along line B-B and including a grounding configuration according to a fourth example.

FIG. 8 is a partial cross-sectional view illustration of the head-mounted device of FIG. 1 taken along line B-B and including a grounding configuration according to a fifth example.

FIG. 9 is a partial cross-sectional view illustration of the head-mounted device of FIG. 1 taken along line B-B and including a grounding configuration according to a sixth example.

FIG. 10 is a schematic view illustration of a connector according to an example.

FIG. 11 is an isometric, cross-sectional view illustration of a flexible cable according to an example.

FIG. 12 is an isometric view illustration of the signal path of the flexible cable of FIG. 11 according to an example.

### DETAILED DESCRIPTION

The disclosure herein relates to electrical grounding configurations that may reduce the likelihood and/or severity of electrostatic discharge (ESD) events and/or electrostatic coupling events on components of an electronic device. Such events may disrupt the intended performance of the electronic device by subjecting the electronic device to unwanted electromagnetic fields and electromagnetic interference (EMI).

When electrostatic charge accumulates on one component of an electronic device disproportionately to another component of the electronic device, a voltage potential between the two components increases. When a threshold voltage potential is exceeded, an ESD event may occur. The threshold voltage potential is influenced by factors such as, for example, the distance between the two components and the properties of the medium that separates the two components (e.g., moisture content in the air between the two components).

To prevent a disproportionate buildup of electrostatic charge on components of an electronic device, the components may be electrically connected to a common ground component (discharge component) via one or more low impedance paths. Such a common ground component may be a metal frame (chassis) of the electronic device or may be some other conductive component. In some implementations, the common ground component may be the Earth.

By providing low impedance paths from the components to a common ground component, electrostatic charge that accumulates on a component may be quickly (e.g., instantaneously) directed to the common ground component, whereby the electrostatic charge will be distributed throughout the common ground component as well as to other components electrically connected to the common ground component. Distributing the electrostatic charge throughout the common ground component and to components electrically connected thereto may reduce the likelihood and/or severity of electrostatic coupling. Furthermore, a voltage potential between components that are electrically connected to the common ground component via low impedance paths may be suppressed, thereby reducing the likelihood and/or severity of an ESD event.

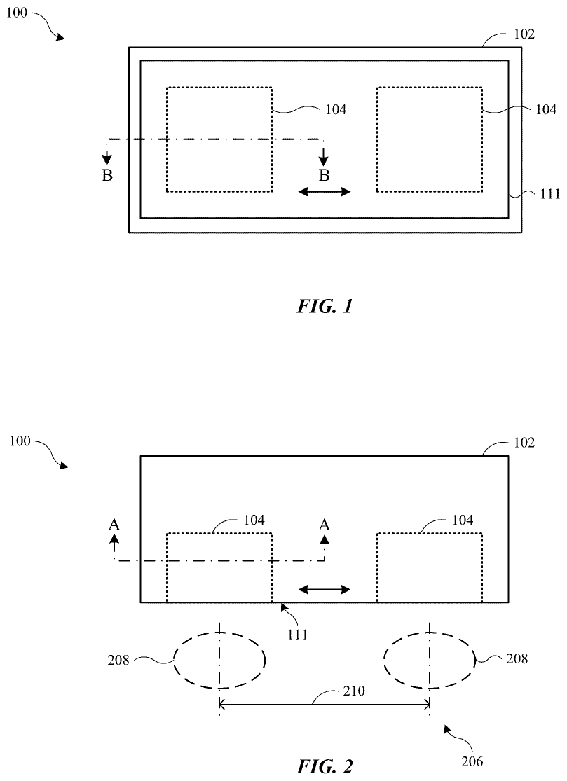

FIG. 1 is a front view illustration of a head-mounted device 100 and FIG. 2 is a top view illustration of the head-mounted device 100. The head-mounted device 100 may include a housing 102 inside which components (electronic components and non-electronic components) may be disposed or partially disposed. Among these components may include optical modules 104 (e.g., two of the optical modules 104) that are configured to display content to a user 206 of the head-mounted device 100. The user 206 has eyes 208 to which the optical modules 104 direct content. The eyes 208 are spaced by an interpupillary distance 210, and the optical modules 104 may be movable (translatable) relative to the housing 102 in order to adjust their positions according to the interpupillary distance 210. To enable the optical module 104 to translate relative to the housing 102, the housing 102 may include a compliant portion 111 through which the optical module 104 may extend.

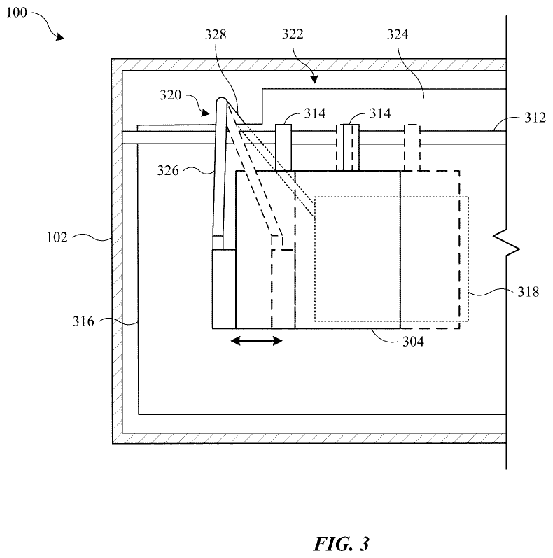

FIG. 3 is a partial cross-sectional view of the head-mounted device 100 taken along line A-A of FIG. 2, showing an optical module 304 in a first position (depicted with solid lines) and showing the optical module 304 in a second position (depicted with broken lines). The optical module 304 may be one of the optical modules 104 described above. The head-mounted device 100 may include a laterally extending member 312 that extends in a lateral direction within the housing 102 of the head-mounted device 100. The optical module 304 may include mounting features 314 that connect the optical module 304 to the laterally extending member 312. The optical module 304 may translate along the laterally extending member 312 to, for example, allow for an adjustment of the interpupillary distance 210 of the user 206. In certain implementations, the laterally extending member 312 may be a lead screw having threads, and the mounting features 314 of the optical module 304 may include complementary threads, such that rotation of the laterally extending member 312 (e.g., by an actuator) translates the optical module 304 along the laterally extending member 312. Other mechanisms may be used to move the optical module 304 with respect to the housing 102 for the purpose of interpupillary distance adjustment.

The head-mounted device 100 may include a frame 316 (e.g., a chassis). The frame 316 may support components within the housing 102 of the head-mounted device 100, such as the laterally extending member 312, and may be fixed relative to the housing 102. The optical module 304 may be electrically connected to other components of the head-mounted device 100, such as a control board 318 (depicted with dotted lines). Accordingly, the head-mounted device 100 may include a flexible cable 320 (e.g., a flexible electrical connector) that electrically connects (couples) the optical module 304 to the control board 318 in order to allow the optical module 304 to translate relative to the housing 102, the frame 316, and/or the control board 318 while maintaining an electrical connection with the control board 318.

Furthermore, as shown in FIG. 3, the frame 316 may be positioned between the optical module 304 and the control board 318 to define a first side 322 of the frame 316 that is near the control board 318 and a second side 324 of the frame 316 that is near the optical module 304. In such an implementation, the flexible cable 320 may be routed around the frame 316. Although FIG. 3 depicts the frame 316 being positioned between the optical module 304 and the control board 318, in other implementations any other component of the head-mounted device 100 may be positioned between the optical module 304 and the control board 318 rather than the frame 316. In such an implementation, the first side 322 and the second side 324 may be defined on the other component of the head-mounted device 100 rather than on the frame 316. Examples of other components that may be positioned between the optical module 304 and the control board 318 include fans, heat sinks, support structures, printed circuit boards (PCBs), the laterally extending member 312, or any other components of the head-mounted device 100. Furthermore, although the frame 316 is depicted as having an opening located on the upper, outboard area of the head-mounted device 100 through which the flexible cable 320 is routed, the frame 316 may have any shape that has any configuration of openings through/around which the flexible cable 320 may be routed.

The flexible cable 320 allows the optical module 304 to translate relative to the housing 102 while maintaining an electrical connection to the control board 318 by flexing during translation of the optical module 304. As shown in FIG. 3, during translation of the optical module 304, the flexible cable 320 may flex along a second portion 326 of the flexible cable 320 that is on the second side 324 of the frame 316, while other portions of the flexible cable 320 remain relatively undisturbed. In other implementations, during translation of the optical module 304, the flexible cable 320 may flex along other portions of the flexible cable 320, such as along a first portion 328 that is on the first side 322 of the frame 316. In other implementations, during translation of the optical module 304, the entire length of the flexible cable 320 may flex.

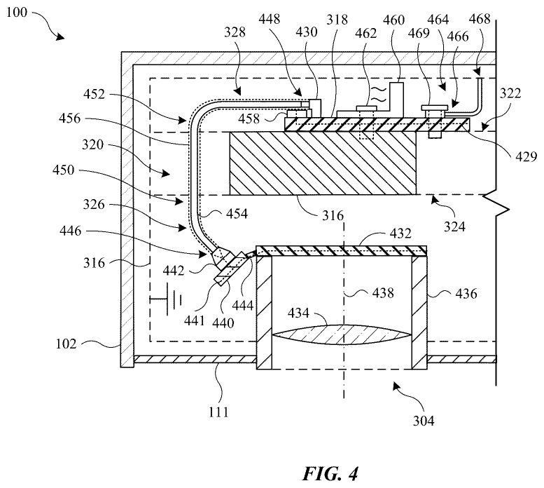

FIG. 4 is a partial cross-sectional view of the head-mounted device 100 taken along line B-B of FIG. 1 and showing the flexible cable 320 electrically connecting (electrically coupling) the optical module 304 to the control board 318. In this implementation, the control board 318 is fixed relative to the housing 102 and the frame 316. The control board 318 may include various electronic components such as a central processing unit (CPU), a graphics processing unit (GPU), random access memory (RAM), a hard disk drive (HDD), a solid-state drive (SSD), and/or integrated circuits. Furthermore, the control board 318 may include a control board grounding path 429 that may provide a common ground for components of the control board 318. The control board grounding path 429 is a conductive structure that is integrated into the control board 318 in order to provide a common ground for components of the control board 318. The control board grounding path 429 may facilitate connection to a common ground component of the head-mounted device 100, such as the frame 316, as explained in further detail below.

The control board 318 may include a control board connector 430 that is connectable to the flexible cable 320. The control board connector 430 may provide an electrical path from the flexible cable 320 to electronic components of the control board 318. The control board connector 430 may have any suitable configuration that allows the flexible cable 320 to connect thereto. For example, the control board connector 430 may include any number of pins (contacts) (e.g., five pins, ten pins, twenty pins, or one hundred pins) that are arranged in any configuration (e.g., side-by-side or as an array). The control board connector 430 may connect to the control board 318 to define a first connection orientation. For example, as shown in FIG. 4, the control board connector 430 may be a right-angle connector wherein the first connection orientation is an orientation where the control board connector 430 faces outboard of the head-mounted device 100. In other implementations, the first connection orientation may be an orientation where the control board connector 430 faces some other direction (e.g., inboard, up, down, or some other direction). In some implementations, the control board connector 430 may not be a right-angle connector (e.g., may be a vertical connector). Furthermore, the control board connector 430 may be connected to the control board 318 at any suitable location.

The control board 318 may be any suitable shape and may be positioned at any suitable orientation within the housing 102 of the head-mounted device 100. As shown in FIG. 4, the control board 318 may be supported by the frame 316 on the first side 322 of the frame 316. However, in other implementations the control board 318 may be supported by the frame 316 at another location on the frame 316, or may be supported by other components of the head-mounted device 100. The control board 318 may be secured to the frame 316 (or other component of the head-mounted device 100) via any suitable means. For example, the control board 318 may be secured to the frame 316 via one or more of threaded fasteners, adhesives, clips, or the like. Furthermore, as shown in FIG. 4, the control board 318 may be oriented such that it is substantially parallel with a back surface of the housing 102 of the head-mounted device 100. However, in other implementations, the control board 318 may have some other orientation relative to the head-mounted device 100.

The optical module 304 may include a display panel 432, a lens 434, and a bezel 436. The display panel 432 may be a light-emitting display component, such as a display screen, that is configured to display content to the user 206 that is wearing the head-mounted device 100. For example, the display panel 432 may be a liquid crystal display. As another example, the display panel 432 may be an organic light emitting diode (OLED) display. As another example, the display panel 432 may be a liquid crystal on silicon (LCoS) micro display.

The lens 434 is configured to direct content from the display panel 432 to one of the eyes 208 of the user 206 to allow the user 206 to view the content. The lens 434 may be coupled to the display panel 432 by the bezel 436. The bezel 436 may be configured to support the lens 434 relative to the display panel 432 and to limit motion of the lens 434 relative to the display panel 432. As shown in FIG. 4, in some implementations, the bezel 436 may be substantially tubular and may define an optical axis 438 that extends therethrough. The display panel 432 and the lens 434 may be spaced along the optical axis 438. Light emitted by the display panel 432 may travel generally along the optical axis 438 of the bezel 436 from the display panel 432 to the lens 434, whereby the light passes through the lens 434 and to one of the eyes 208 of the user 206.

The optical module 304 may also include an optical module control board 440. The optical module control board 440 may be electrically connected to the display panel 432 and may be configured to provide a signal to the display panel 432 (e.g., to provide the content to the display panel 432). For example, the display panel 432 may be configured to show the content based on the signal received from the optical module control board 440. In some implementations, the optical module control board 440 may include one or more integrated circuits, memory components, or other electronic components, such as those described above with respect to the control board 318. Furthermore, the optical module control board 440 may include an optical module grounding path 441 that may provide a common ground for components of the optical module 304. The optical module grounding path 441 is a conductive structure that is integrated into the optical module control board 440 in order to provide a common ground for components of the optical module control board 440. The optical module grounding path 441 may facilitate connection to a common ground component of the head-mounted device 100, such as the frame 316, as explained in further detail below.

The optical module control board 440 may also include an optical module connector 442 that is connectable to the flexible cable 320. The optical module connector 442 may provide an electrical path from the flexible cable 320 to electronic components of the optical module 304. Similar to the control board connector 430, the optical module connector 442 may have any suitable configuration and may be located at any suitable location on the optical module control board 440. Furthermore, similar to the control board connector 430, the optical module connector 442 may be connected to the optical module control board 440 to define a second connection orientation. As shown in FIG. 4, the second connection orientation may be an orientation in which the optical module connector 442 faces in a rear, outboard direction of the head-mounted device 100. However, in other implementations, the second connection orientation may be an orientation where the optical module connector 442 faces some other direction (e.g., inboard, up, down, or some other direction).

The optical module 304 may also include a flexible connector 444 that is configured to electrically connect the display panel 432 to the optical module control board 440. The flexible connector 444 may allow the optical module control board 440 to provide a signal to the display panel 432. For example, the optical module control board 440 may be configured to provide the signal for the content to the display panel 432 via the flexible connector 444. Furthermore, in some implementations, the flexible connector 444 may connect the optical module grounding path 441 to the display panel 432 in order to provide a common ground for components of the display panel 432, and components thereof. The flexible connector 444 may be flexible in order to further enable the optical module 304 to translate while maintaining an electrical connection between the control board 318 and the display panel 432. In some implementations, the flexible connector 444 may be a flexible flat cable, a flexible printed circuit, a flexible ribbon cable, or any other electrical connector suitable to facilitate a flexible connection between the optical module control board 440 and the display panel 432.

The flexible cable 320 may include a first end 446 configured to connect to the optical module connector 442, a second end 448 configured to connect to the control board connector 430, and a central portion 450 extending therebetween. As shown in FIG. 4, the central portion 450 may be routed around the frame 316 to define a bend 452. The bend 452 may aid in routing the flexible cable 320 around the frame 316. Furthermore, as described above, the control board connector 430 and the optical module connector 442 may be positioned at a first connection orientation and a second connection orientation, respectively, wherein the first connection orientation and the second connection orientation are different. Thus, the bend 452 may also aid in orienting the first end 446 of the flexible cable 320 to be consistent with the second connection orientation of the optical module connector 442, and may aid in orienting the second end 448 of the flexible cable 320 to be consistent with the first connection orientation of the control board connector 430. Although the bend 452 is depicted as being located at a rear, outboard area of the head-mounted device 100, it will be readily understood that the bend 452 may not be located at a specific location along the flexible cable 320 and may instead change locations along the flexible cable 320 during operation of the head-mounted device 100 (e.g., during translation of the optical module 304). Furthermore, the bend 452 may be located in other areas of the head-mounted device 100 depending on the positions of the frame 316, the optical module 304, the control board 318, and/or other components of the head-mounted device 100.

The flexible cable 320 includes a signal path 454 that is configured to transmit (e.g., is configured to facilitate communication) of an electrical signal between the optical module 304 and the control board 318. The electrical signal may be electrical information related to operation of the display panel 432 (e.g., may be a signal for the content) or may be other electrical information related to other operations of the head-mounted device 100.

The flexible cable 320 may also include a conductive shield 456 (e.g., a conductive shielding material) that is configured to prevent (reduce) EMI with the electrical signal as it is transmitted along the signal path 454 between the optical module 304 and the control board 318. The conductive shield 456 may prevent EMI with the electrical signal by reflecting and/or absorbing EMI that may otherwise interfere with the electrical signal (e.g., that would otherwise cause noise in the electrical signal). In some implementations, the conductive shield 456 may define an exterior surface of the flexible cable 320.

In certain implementations, the conductive shield 456 may be electrically connected (coupled) to the optical module grounding path 441 to provide a low impedance path between the conductive shield 456 and the optical module grounding path 441. Furthermore, the conductive shield 456 may be electrically connected (coupled) to the control board grounding path 429 to provide a low impedance path between the conductive shield 456 and the control board grounding path 429. The low impedance paths provided by the conductive shield 456 may allow for electrostatic charge (electrical charge) to be transferred between the optical module grounding path 441 and the control board grounding path 429.

The optical module connector 442 may be configured to provide a first electrical path between the electronic components of the optical module 304 and the signal path 454 of the flexible cable 320 through which the electrical signal may travel, and a second electrical path between the optical module grounding path 441 and the conductive shield 456 of the flexible cable 320 through which electrostatic charge (electrical charge) may travel. Likewise, the control board connector 430 may provide a first electrical path between electronic components of the control board 318 and the signal path 454, and a second electrical path between the control board grounding path 429 and the conductive shield 456.

In some implementations, however, rather than the control board connector 430 providing the second electrical path between the control board grounding path 429 and the conductive shield 456 of the flexible cable 320, a conductive gasket 458 may be positioned between the flexible cable 320 and the control board 318, wherein the conductive gasket 458 provides the second electrical path between the control board grounding path 429 and the conductive shield 456. As shown in FIG. 4, in some implementations, the conductive gasket 458 may be positioned at the second end 448 of the flexible cable 320 (e.g., adjacent to the control board connector 430). However, in other implementations, the conductive gasket 458 may not be positioned at the second end 448 of the flexible cable 320 and may instead be positioned between the flexible cable 320 and the control board 318 at another location along the flexible cable 320.

Similarly, in some implementations, rather than the optical module connector 442 providing the second electrical path between the optical module grounding path 441 and the conductive shield 456 of the flexible cable 320, the conductive gasket 458 may be positioned between the flexible cable 320 and the optical module control board 440 to provide the low impedance path between the conductive shield 456 and the optical module grounding path 441. In some implementations, the conductive gasket 458 may be positioned at the first end 446 of the flexible cable 320 (e.g., adjacent to the optical module connector 442). However, in other implementations, the conductive gasket may instead be positioned between the flexible cable 320 and the optical module control board 440 at another location along the flexible cable 320. Furthermore, in some implementations, more than one (e.g., two) of the conductive gasket 458 may be employed, wherein one is positioned between the control board 318 and the flexible cable 320 and the other is positioned between the optical module control board 440 and the flexible cable 320 to provide low impedance paths between the control board grounding path 429 and the conductive shield 456 and between the optical module grounding path 441 and the conductive shield 456, respectively.

The conductive gasket 458 may be comprised of a conductive and compressible material that may be compressed between the flexible cable 320 and the control board 318 and/or between the flexible cable 320 and the optical module control board 440. For example, the conductive gasket 458 may be comprised of a conductive foam (e.g., polyethylene foam filled with carbon). As another example, the conductive gasket 458 may be comprised of a conductive silicone (e.g., silicone filled with nickel-graphite). Furthermore, the conductive gasket 458 may be secured to the flexible cable 320, the control board 318, and/or the optical module control board 440 via conductive adhesives, conductive tape, or the like.

The head-mounted device 100 may also include one or more grounding members that provide low impedance paths that extend from the conductive shield 456, the control board grounding path 429, the optical module grounding path 441, and/or another grounding path of another component of the head-mounted device 100 to a common ground component of the head-mounted device 100. In certain implementations, the common ground component may be the frame 316. In other implementations, the common ground component may be some other conductive component of the head-mounted device 100. By providing one or more low impedance paths from the conductive shield 456, the control board grounding path 429, the optical module grounding path 441, and/or another grounding path of another component of the head-mounted device 100 to the frame 316, electrostatic charge (electrical charge) may be directed away from the optical module 304, the flexible cable 320, the control board 318 and/or another component of the head-mounted device 100 and directed to the frame 316. The term grounding member as used herein refers to any component of the head-mounted device 100 that provides a low impedance electrical connection from a component of the head-mounted device 100 to the common ground component of the head-mounted device 100.

The head-mounted device 100 may also include a fan 460 disposed within the housing 102 of the head-mounted device 100 that is configured to circulate air within an interior the head-mounted device 100. The fan 460 may be supported by the frame 316. As shown in FIG. 4, in certain implementations, the control board 318 may be positioned between the fan 460 and the frame 316. In such an implementation, a conductive fastener 462 (e.g., a conductive screw, a conductive bolt, or other type of fastener) may extend through the control board 318 and into the frame 316 in order to secure the fan 460 and/or the control board 318 to the frame 316. Furthermore, when the conductive fastener 462 extends through the control board 318, the conductive fastener 462 may contact the control board grounding path 429 and provide a low impedance path between the control board grounding path 429 and the frame 316 (e.g., the conductive fastener 462 may be a grounding member as described above). The conductive fastener 462 may be comprised of any conductive material (e.g., copper, aluminum, steel, brass), or may be coated with any conductive material, that may facilitate a low impedance path form the control board grounding path 429 to the frame 316.

In implementations where the conductive fastener 462 secures the fan 460 to the frame 316 by extending through the control board 318, the fan 460 and the conductive fastener 462 may be positioned anywhere on the control board 318 where the control board grounding path 429 is routed, such that the conductive fastener 462 may contact the control board grounding path 429. Furthermore, in some implementations, the fan 460 may be omitted, wherein the conductive fastener 462 does not secure the fan 460 to the frame 316 and is operable only to secure the control board 318 to the frame 316 and/or to provide a low impedance path from the control board grounding path 429 to the frame 316.

The head-mounted device 100 may also include a grounding strap 464 that electrically connects (couples) the control board 318 to the frame 316 to provide a low impedance path from the control board grounding path 429 to the frame 316 (e.g., the grounding strap 464 may be a grounding member as described above). The grounding strap 464 may include a first end 466 that is configured to connect to the control board 318 and a second end 468 that is configured to connect to the frame 316. In some implementations, the first end 466 may directly contact the control board grounding path 429 to provide a low impedance path therebetween. In such an implementation, a mounting fastener 469 (e.g., a screw, a bolt, or other type of fastener) may extend through the first end 466 and into the control board 318 to secure the first end 466 to the control board grounding path 429. In other implementations, the first end 466 may be secured to the control board grounding path 429 via other suitable means, such as via clips, adhesives, or the like.

In other implementations, the first end 466 may not directly contact the control board grounding path 429, but rather the mounting fastener 469 may directly contact the control board grounding path 429. In such an implementation, the mounting fastener 469 may extend through the first end 466 of the grounding strap 464 and into (e.g., through) the control board 318 to contact the control board grounding path 429. In implementations where the mounting fastener 469 directly contacts the control board grounding path 429, the mounting fastener 469 may be comprised of a conductive material (e.g., copper, aluminum, steel, brass), or may be coated with a conductive material, in order to provide a low impedance path between the control board grounding path 429 and the grounding strap 464. However, in other implementations where the mounting fastener 469 does not provide a low impedance path from the control board grounding path 429 to the grounding strap 464, the mounting fastener 469 may not be comprised of a conductive material (e.g., may be comprised of a non-conductive material). Furthermore, although in the illustrated implementation the mounting fastener 469 does not directly connect the control board 318 to the frame 316, in some implementations, the mounting fastener 469 may extend through the control board 318 and into the frame 316 to secure the control board 318 to the frame 316.

The grounding strap 464 is comprised of a conductive material (e.g., copper, aluminum, steel, brass) that allows electrostatic charge (electrical charge) to travel thereon. In some implementations, the grounding strap 464 may be flexible. In such an implementation, the grounding strap 464 may include conductive strands arranged in a woven fabric (mesh) configuration, a braided configuration, a twisted configuration, or in another configuration. In other implementations, the grounding strap 464 may include a single wire or multiple wires. The second end 468 of the grounding strap 464 may be electrically connected (coupled) to the frame 316 via any suitable means that allow for a low impedance path to be maintained therebetween. For example, the second end 468 of the grounding strap 464 may be electrically connected to the frame 316 via one or more of fasteners, clips, or the like.

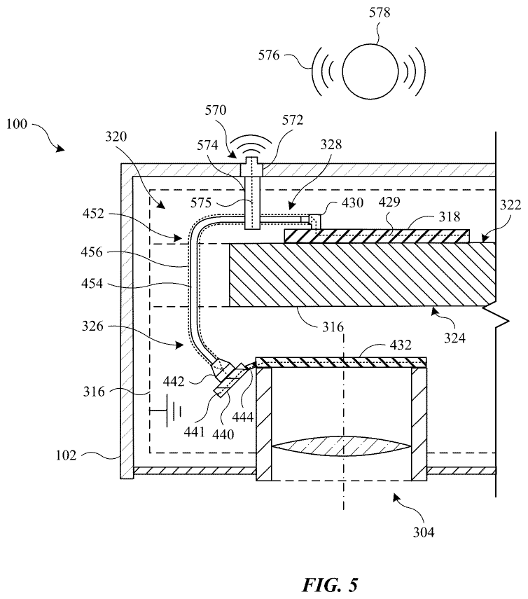

FIG. 5 is a partial cross-sectional view of the head-mounted device 100 taken along line B-B of FIG. 1 and showing another grounding configuration that includes an antenna assembly 570. The antenna assembly 570 may be disposed within the housing 102 of the head-mounted device 100 and/or may extend through the housing 102. The antenna assembly 570 may include an antenna 572 and a grounding clip 574. The antenna 572 may be configured to receive wireless signals 576 from a signal source 578. The wireless signals 576 may be information related to the operation of the head-mounted device 100. The signal source 578 may be an electronic component of the head-mounted device 100, or may be some other electronic component (e.g., a personal computer or a smartphone), that is configured to emit the wireless signals 576. The antenna assembly 570 may be positioned on/within the head-mounted device 100 at any suitable location that allows for the antenna 572 to receive the wireless signals 576.

The antenna 572 includes an antenna grounding path 575. The antenna grounding path 575 is a conductive structure that is integrated into the antenna 572 in order to provide a common ground for the antenna 572, and components thereof. The grounding clip 574 is electrically connected to the antenna grounding path 575 and may further define the antenna grounding path 575. In some implementations, the grounding clip 574 may also be electrically connected (coupled) to the conductive shield 456 of the flexible cable 320 in order to provide a low impedance path from the antenna grounding path 575 to the frame 316 (e.g., the conductive shield 456 may be a grounding member as described above). In such an implementation, the antenna grounding path 575 may be in conductive communication (e.g., electrically connected by a low-impedance electrical connector) with the conductive shield 456 and the frame 316 via any of the grounding configurations described herein. In some implementations, the antenna grounding path 575 may be in conductive communication with the frame 316 through the control board grounding path 429. For example, where the antenna grounding path 575 is electrically connected to the conductive shield 456, the conductive shield 456 may be electrically connected to the control board grounding path 429 via the control board connector 430 and/or the conductive gasket 458. The control board grounding path 429 may be connected to the frame 316 via the conductive fastener 462, the grounding strap 464, a grounding tab (described in further detail below), or a grounding cable (described in further detail below), thus providing a low impedance path between the antenna grounding path 575 and the frame 316.

As shown in FIG. 5, the grounding clip 574 may be connected to the flexible cable 320 along the first portion 328 of the flexible cable 320. In other implementations, however, the grounding clip 574 may be connected to other portions of the flexible cable 320 depending on the location of the antenna assembly 570 (e.g., along the second portion 326 or the bend 452). In some implementations, the grounding clip 574 may be configured to directly connect the antenna 572 to the frame 316 to provide a low impedance path directly from the antenna grounding path 575 to the frame 316 through a portion of the antenna grounding path 575 that is defined by the grounding clip 574 (e.g., the grounding clip 574 may be a grounding member as described above). Furthermore, in such an implementation, the grounding clip 574 may also be connected to the conductive shield 456 to provide a low impedance path from the conductive shield 456, and any components electrically connected thereto, to the frame 316. Thus, electrostatic charge (electrical charge) may be directed from the conductive shield 456, and any components electrically connected thereto, to the frame 316 through the grounding clip 574. For example, where the conductive shield 456 is electrically connected to the control board grounding path 429, the grounding clip 574 and the conductive shield 456 may cooperatively provide a low impedance path from the control board grounding path 429 to the frame 316 through the portion of the antenna grounding path 575 that is defined by the grounding clip 574.

In implementations where the grounding clip 574 is electrically connected to the flexible cable 320 and to the frame 316, the grounding clip 574 may also be configured to retain portions of the flexible cable 320 to the frame 316. By retaining portions of the flexible cable 320 to the frame 316, the grounding clip 574 may aid in routing the flexible cable 320 within the head-mounted device 100. In certain implementations, the grounding clip 574 may define the location of the bend 452 of the flexible cable 320. Additionally, by retaining portions of the flexible cable 320 to the frame 316, the grounding clip 574 may influence which portions of the flexible cable 320 flex during translation of the optical module 304. For example, in certain implementations the grounding clip 574 may be connected to the first portion 328 of the flexible cable 320 and the grounding clip 574 may retain the first portion 328 to the frame 316. During translation of the optical module 304, the first portion 328 of the flexible cable 320 may be held relatively still by the grounding clip 574 while other portions of the flexible cable 320 (e.g., the second portion 326 and/or the bend 452) flex to accommodate the movement of the optical module 304.

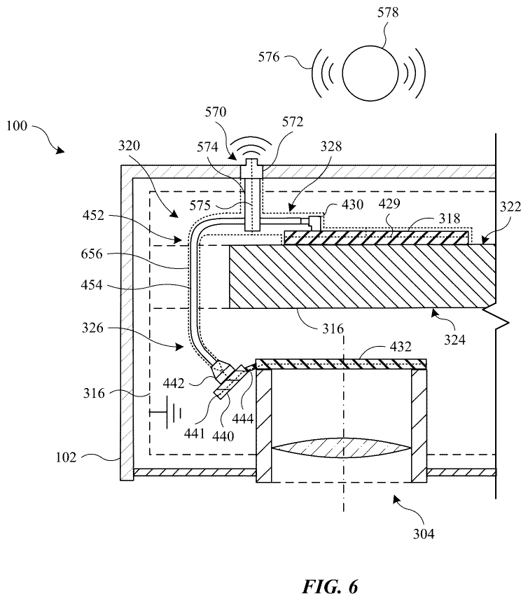

FIG. 6 is a partial cross-sectional view of the head-mounted device 100 taken along line B-B of FIG. 1 and showing another grounding configuration that includes a conductive shield 656. The conductive shield 656 may be similar to the conductive shield 456 except as described herein. In some implementations, the conductive shield 656 may not be included as a component of the flexible cable 320 but may rather be a separate component of the head-mounted device 100. As shown in FIG. 6, the conductive shield 656 may extend over the flexible cable 320 and the control board 318. In other implementations, the conductive shield 656 may extend over only a portion of the flexible cable 320 and/or over only a portion of the control board 318. The conductive shield 656 may be configured to prevent (reduce) EMI with the electrical signal as it travels along the signal path 454 of the flexible cable 320. The conductive shield 656 may also prevent EMI with the control board 318 or components thereof. Furthermore, the conductive shield 656 may extend over the control board 318 and contact the control board grounding path 429 to provide a low impedance path between the conductive shield 656 and the control board grounding path 429 (e.g., the conductive shield 656 may be a grounding member as described above). In some implementations, the conductive shield 656 may be conductive tape that is wrapped around the flexible cable 320 and that is extended over the control board 318. In other implementations, the conductive shield 656 may be a sheet of conductive material (e.g., conductive foil) that extends over the flexible cable 320 and the control board 318.

Additionally, in some implementations, the conductive shield 656 may extend over the antenna assembly 570 to prevent (reduce) EMI with the wireless signals 576 received by the antenna 572. The conductive shield 656 may also contact the grounding clip 574 to provide a low impedance path between the conductive shield 656 and the antenna grounding path 575.

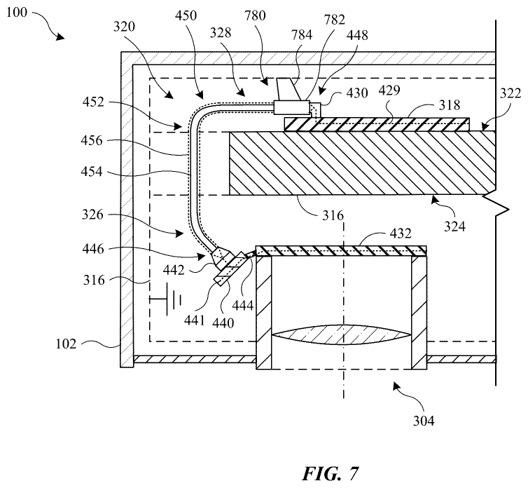

FIG. 7 is a partial cross-sectional view of the head-mounted device 100 taken along line B-B of FIG. 1 and showing another grounding configuration that includes a grounding tab 780. The grounding tab 780 may electrically connect the conductive shield 456 of the flexible cable 320 to the frame 316. By electrically connecting (coupling) the conductive shield 456 to the frame 316, the grounding tab 780 may provide a low impedance path from the conductive shield 456 to the frame 316 (e.g., the grounding tab 780 may be a grounding member as described above). The grounding tab 780 may include a connecting member 782 and a tab member 784. The connecting member 782 may be electrically connected to the conductive shield 456 of the flexible cable 320. The tab member 784 may electrically connect the connecting member 782 to the frame 316.

In some implementations, the connecting member 782 may include a recessed portion that is configured to receive the flexible cable 320. In other implementations, the connecting member 782 may extend around a diameter of the flexible cable 320 (e.g., may be a collar). In other implementations, the connecting member 782 may be a clip that includes an opening configured to receive the flexible cable 320. Furthermore, as shown in FIG. 7, the connecting member 782 may be connected to the flexible cable 320 adjacent to the second end 448 (e.g., adjacent to the control board connector 430). In other implementations, the connecting member 782 may not be connected to the flexible cable 320 adjacent to the second end 448, but instead may be positioned at other locations along the flexible cable 320. For example, the connecting member 782 may be connected to the flexible cable 320 along the first portion 328, the second portion 326, or the bend 452. As another example, the connecting member 782 may be connected to the flexible cable 320 adjacent to the first end 446 (e.g., adjacent to the optical module connector 442). The connecting member 782 may be comprised of any configuration of any conductive material that facilitates a low impedance path between the conductive shield 456 of the flexible cable 320 and the frame 316. For example, the connecting member 782 may include a conductive material (e.g., copper, aluminum, steel, brass) on an inner surface of the connecting member 782 that contacts the conductive shield 456, and may include an insulative material on an outer surface. As another example, the connecting member 782 may be comprised entirely of a conductive material.

The tab member 784 of the grounding tab 780 is comprised of a conductive material (e.g., copper, aluminum, steel, brass) to allow electrostatic charge (electrical charge) to travel thereon. The tab member 784 may be an elongated member that is substantially rigid. In some implementations, however, the tab member 784 may be configured to elastically deform. As shown in FIG. 7, the tab member 784 may be connected to the frame 316 at a rear, medial location of the frame 316. In other implementations, the tab member 784 may be connected to the frame 316 at any other suitable location on the frame 316 that is proximate to the flexible cable 320. The tab member 784 may be connected to the frame 316 via any suitable means. For example, the tab member 784 may be connected to the frame 316 via one or more fasteners, clips, or the like. In some implementations, the grounding tab 780 may be formed integrally with the frame 316.

In some implementations, such as implementations where the tab member 784 is configured to elastically deform, the grounding tab 780 may omit the connecting member 782, wherein the tab member 784 may contact the conductive shield 456 of the flexible cable 320. In such an implementation, the tab member 784 may be configured to clamp onto the flexible cable 320 to secure the grounding tab 780 thereto.

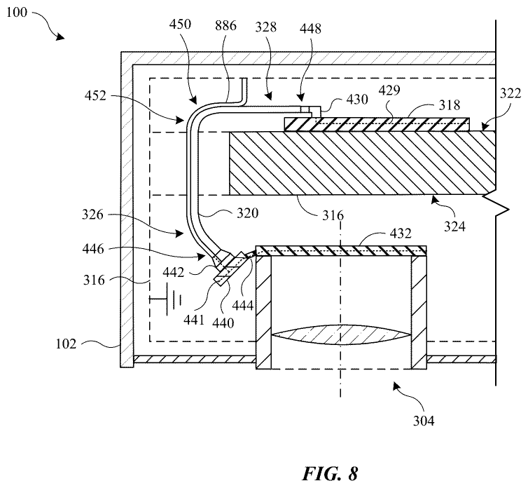

FIG. 8 is a partial cross-sectional view of the head-mounted device 100 taken along line B-B of FIG. 1 and showing another grounding configuration that includes a grounding cable 886. The grounding cable 886 may electrically connect to the optical module grounding path 441 to the frame 316 to provide a low impedance path from the optical module grounding path 441 to the frame 316 (e.g., the grounding cable 886 may be a grounding member as described above). The grounding cable 886 may be connected to the optical module grounding path 441 by connecting to the optical module connector 442, wherein the optical module connector 442 provides an electrical path between the optical module grounding path 441 and the grounding cable 886. As shown in FIG. 8, in some implementations, the grounding cable 886 may be connected to the frame 316 on the first side 322 of the frame 316 adjacent to the housing 102. The grounding cable 886 may be connected to the frame via any suitable means. For example, the grounding cable 886 may be connected to the frame 316 via one or more fasteners, clips, or the like.

In some implementations, the grounding cable 886 may extend from the optical module connector 442 and along a portion of the flexible cable 320, whereby the grounding cable 886 separates from the flexible cable 320 before connecting to the frame 316. The grounding cable 886 may separate from the flexible cable 320 on the same side of the frame 316 that the grounding cable 886 is connected to. For example, as shown in FIG. 8, the grounding cable 886 is connected to frame 316 on the first side 322 of the frame 316 and the grounding cable 886 also separates from the flexible cable 320 on the first side 322 of the frame 316. In some implementations, the grounding cable 886 may separate from the flexible cable 320 at a location along the flexible cable 320 between the bend 452 and the control board connector 430. The grounding cable 886 may be secured along the flexible cable 320 prior to the grounding cable 886 separating from the flexible cable 320 via any suitable means, such as via ties, adhesives, clips, or the like.

The grounding cable 886 may be comprised of an elongated conductor (e.g., a wire). In some implementations where the grounding cable 886 is comprised of an elongated conductor, the elongated conductor may not include insulation on its outer surface (e.g., may be non-insulated). Thus, the grounding cable 886 may include a non-insulated conductor that extends along a portion of the flexible cable 320 (e.g., a flexible electrical connector), in contact with the exterior of the flexible cable 320, in order to provide a path to ground from the exterior of the flexible cable 320 to a grounding member, such as the frame 316. In other implementations where the grounding cable 886 is comprised of an elongated conductor, the elongated conductor may include insulation on its outer surface (e.g., may be insulated). In other implementations, the grounding cable 886 may be comprised of multiple elongated conductors (e.g., multiple wires). In such an implementation, the elongated conductors may or may not be insulated. The grounding cable 886 may be comprised of any conductive material (e.g., copper, aluminum, steel, brass) that may allow electrostatic charge (electrical charge) to travel thereon. The grounding cable 886 may be secured along the flexible cable 320 prior to the grounding cable 886 separating from the flexible cable 320 via any suitable means, such as via ties, adhesives, clips, or the like.

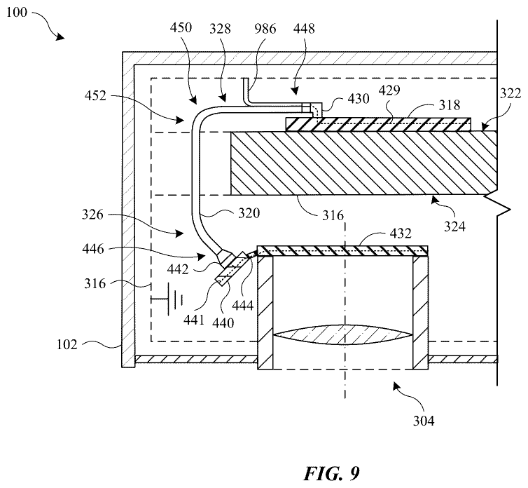

FIG. 9 is a partial cross-sectional view of the head-mounted device 100 taken along line B-B of FIG. 1 and showing another grounding configuration that includes a grounding cable 986. The grounding cable 986 may be similar to the grounding cable 886 except as described herein. The grounding cable 986 may electrically connect the control board grounding path 429 to the frame 316 to provide a low impedance path from the control board grounding path 429 to the frame 316 (e.g., the grounding cable 986 may be a grounding member as described above). The grounding cable 986 may be connected to the control board grounding path 429 by connecting to the control board connector 430, wherein the control board connector 430 provides an electrical path between the control board grounding path 429 and the grounding cable 986. As shown in FIG. 9, in some implementations, the grounding cable 986 may be connected to the frame 316 on the first side 322 of the frame 316 adjacent to the housing 102. The grounding cable 986 may be connected to the frame 316 via any suitable means. For example, the grounding cable 986 may be connected to the frame 316 via one or more fasteners, clips, or the like.

In some implementations, the grounding cable 986 may extend from the control board connector 430 and along a portion of the flexible cable 320, whereby the grounding cable 986 separates from the flexible cable 320 before connecting to the frame 316. The grounding cable 986 may separate from the flexible cable 320 on the same side of the frame 316 that the grounding cable 986 is connected to. For example, as shown in FIG. 9, the grounding cable 986 is connected to frame 316 on the first side 322 of the frame 316 and the grounding cable 986 also separates from the flexible cable 320 on the first side 322 of the frame 316. In some implementations, the grounding cable 986 may separate from the flexible cable 320 at a location along the flexible cable 320 between the bend 452 and the control board connector 430.

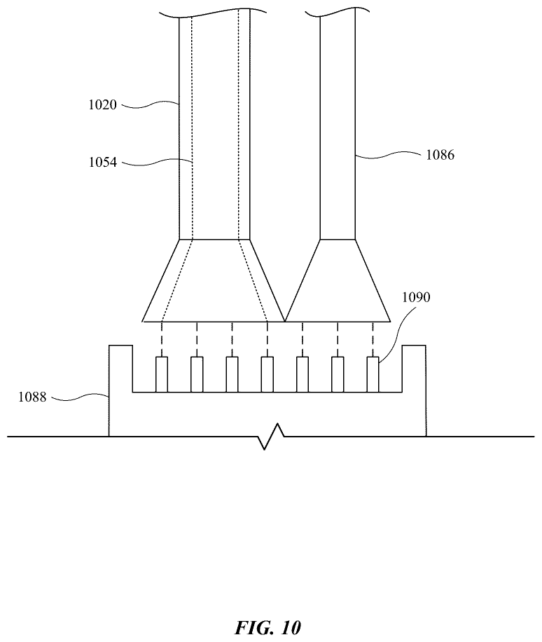

FIG. 10 is a schematic view illustration of a connector 1088. The connector 1088 may be the optical module connector 442 and/or the control board connector 430. The connector 1088 may include pins 1090 (contacts) that are configured to connect to a flexible cable 1020 and/or a grounding cable 1086. The flexible cable 1020 may be similar to the flexible cable 320 and may include a signal path 1054 that is similar to the signal path 454. The grounding cable 1086 may be similar to the grounding cable 986.

In some implementations, a first group of the pins 1090 may be configured to connect to the flexible cable 1020, and a second group of the pins 1090 may be configured to connect to the grounding cable 1086. In implementations where the connector 1088 is the optical module connector 442, the first group of the pins 1090 may be configured to provide an electrical path from the electronic components of the optical module 304 to the signal path 1054 of the flexible cable 1020, and the second group of the pins 1090 may be configured to provide an electrical path from the optical module grounding path 441 to the grounding cable 1086. In implementations where the connector 1088 is the control board connector 430, the first group of the pins 1090 may be configured to provide an electrical path from the electronic components of the control board 318 to the signal path 1054 of the flexible cable 1020, and the second group of the pins 1090 may be configured to provide an electrical path from the control board grounding path 429 to the grounding cable 1086.

As shown in FIG. 10, the connector 1088 may include seven of the pins 1090, wherein the first group of the pins 1090 includes four of the pins 1090 and the second group of the pins 1090 includes three of the pins 1090. However, the connector 1088 may include any number of the pins 1090 that corresponds to a number of complementary contacts on the flexible cable 1020 and on the grounding cable 1086. The number of complementary contacts on the flexible cable 1020 may correspond to a number of wires that comprise the signal path 1054 of the flexible cable 1020, and the number of complementary contacts on the grounding cable 1086 may correspond to a number of wires that comprise the grounding cable 1086. For example, where the signal path 1054 of the flexible cable 1020 includes ten wires and the grounding cable 1086 includes ten wires, the connector 1088 may include twenty of the pins 1090, wherein the first group of the pins 1090 includes ten of the pins 1090 and the second group of the pins 1090 includes ten of the pins 1090.

Furthermore, as shown in FIG. 10, the pins 1090 of the connector 1088 may be arranged in series (e.g., may be arranged in a row). However, in other implementations, the pins 1090 of the connector 1088 may be arranged as an array or as multiple columns of rows. In other implementations, the pins 1090 of the connector 1088 may be arranged in some other configuration.

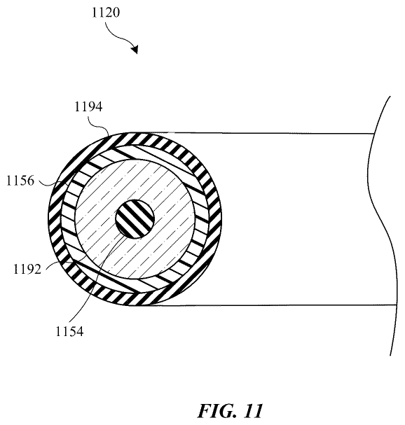

FIG. 11 is an isometric, cross-sectional view illustration of a flexible cable 1120. The flexible cable 1120 may be similar to the flexible cable 320 except as described herein. In certain implementations, the flexible cable 1120 may be a coaxial cable that includes a signal path 1154 (e.g., a conductive core), an insulating layer 1192, a conductive shield 1156 (e.g., a conductive shield layer), and an outer jacket 1194. In some implementations, the flexible cable 1120 may be a micro-coaxial cable (e.g., a coaxial cable having an outer diameter less than 1.2 mm) that includes the same components as described above with respect to a coaxial cable. The signal path 1154 may be similar to the signal path 454, and the conductive shield 1156 may be similar to the conductive shield 456, except as described herein.

The insulating layer 1192 may extend concentrically around (e.g., surround) the signal path 1154. In some implementations, the insulating layer 1192 may be comprised of a dielectric material (e.g., may be a dielectric insulator), such as PTFE, polyethylene, or some other dielectric material. The insulating layer 1192 may insulate the signal path 1154 from the conductive shield 1156 to inhibit the electrical signal and/or electrostatic charge (electrical charge) from traveling therebetween. The insulating layer 1192 may also be operable to prevent a loss of the electrical signal while it is transmitted along the signal path 1154.

The conductive shield 1156 (e.g., the conductive shield layer) may be comprised of an elongated conductor that extends concentrically around (e.g., surrounds) the insulating layer 1192. In some implementations, the conductive shield 1156 may be comprised of strands of the conductive material (e.g., copper, aluminum, steel, brass) that extend around the insulating layer 1192 in a braided configuration. In other implementations, the conductive shield 1156 may be comprised of strands of the conductive material that extend around the insulating layer 1192 in a spiral configuration. In yet other implementations, the conductive material may be a unitary sheet (e.g., foil or tape) that extends around the insulating layer 1192. As described above with reference to FIG. 4, the conductive shield 1156 may be configured to prevent (reduce) EMI with the electrical signal as it is transmitted along the signal path 1154 by reflecting and/or absorbing EMI that may otherwise interfere with the electrical signal (e.g., that may otherwise cause noise in the electrical signal).

The outer jacket 1194 may extend concentrically around (e.g., surround) the conductive shield 1156. The outer jacket 1194 may be nonconductive (e.g., may be a nonconductive outer jacket), wherein the outer jacket 1194 may be comprised of an insulating material (e.g., PVC or polyethylene). The outer jacket 1194 may insulate the conductive shield 1156 from other components of the head-mounted device 100 that the flexible cable 1120 may contact. Thus, in implementations where the conductive shield 1156 provides a low impedance path through which electrostatic charge (electrical charge) may travel, the outer jacket 1194 may inhibit the electrostatic charge from traveling from the conductive shield 1156 to other components of the head-mounted device 100. Additionally, the outer jacket 1194 may protect the conductive shield 1156, and other components of the flexible cable 1120, from physical damage. For example, the outer jacket 1194 may prevent the flexible cable 1120 from becoming pinched during operation of the head-mounted device 100 (e.g., during translation of the optical module 304).

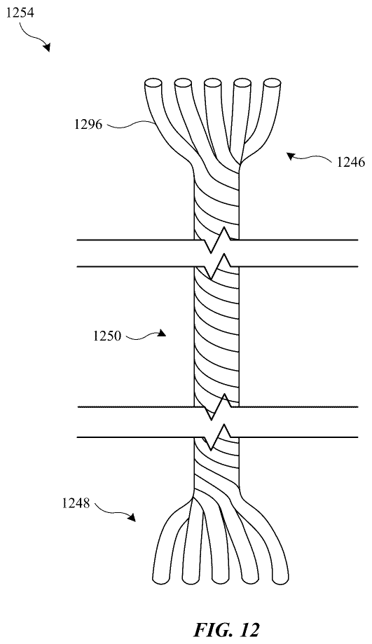

FIG. 12 is an isometric view illustration of the signal path 1154 of the flexible cable 1120 wherein the insulating layer 1192, the conductive shield 1156, and the outer jacket 1194 have been removed for the purpose of clarity. The flexible cable 1120 includes a first end 1246, a second end 1248, and a central portion 1250. The first end 1246 may be similar to the first end 446, the second end 1248 may be similar to the second end 448, and the central portion 1250 may be similar to the central portion 450, except as described herein.

As shown in FIG. 12, in some implementations, the signal path 1254 may be comprised of multiple elongated conductors 1296 (e.g., five of the elongated conductors 1296) that are twisted around one-another (e.g., arranged in a bundle) along the central portion 1250 of the flexible cable 1120. In such an implementation, the elongated conductors 1296 may separate from one-anther at the first end 1246 and at the second end 1248, such that the elongated conductors 1296 are positioned laterally adjacent to one-another. In some implementations, the elongated conductors are wires comprised of a conductive material (e.g., copper, aluminum, steel, brass). In such an implementation, each of the wires may include insulation on the outer surface of the wires such that the wires are insulated relative to each other. In other implementations, the elongated conductors are micro-coaxial cables, each including a conductive core, an insulating layer, a shield layer, and a nonconductive outer jacket. In such an implementation, the outer jacket of each of the micro-coaxial cables may insulate each of the micro-coaxial cables relative to each other. Although FIG. 12 shows an implementation where the signal path 1254 comprises five of the elongated conductors 1296, in other implementations the signal path 1254 may include another number (e.g., ten, twenty, or one hundred) of the elongated conductors 1296.

A physical environment refers to a physical world that people can sense and/or interact with without aid of electronic systems. Physical environments, such as a physical park, include physical articles, such as physical trees, physical buildings, and physical people. People can directly sense and/or interact with the physical environment, such as through sight, touch, hearing, taste, and smell.

In contrast, a computer-generated reality (CGR) environment refers to a wholly or partially simulated environment that people sense and/or interact with via an electronic system. In CGR, a subset of a person's physical motions, or representations thereof, are tracked, and, in response, one or more characteristics of one or more virtual objects simulated in the CGR environment are adjusted in a manner that comports with at least one law of physics. For example, a CGR system may detect a person's head turning and, in response, adjust graphical content and an acoustic field presented to the person in a manner similar to how such views and sounds would change in a physical environment. In some situations (e.g., for accessibility reasons), adjustments to characteristic(s) of virtual object(s) in a CGR environment may be made in response to representations of physical motions (e.g., vocal commands).

A person may sense and/or interact with a CGR object using any one of their senses, including sight, sound, touch, taste, and smell. For example, a person may sense and/or interact with audio objects that create three-dimensional or spatial audio environment that provides the perception of point audio sources in three-dimensional space. In another example, audio objects may enable audio transparency, which selectively incorporates ambient sounds from the physical environment with or without computer-generated audio. In some CGR environments, a person may sense and/or interact only with audio objects.

Examples of CGR include virtual reality and mixed reality.

A virtual reality (VR) environment refers to a simulated environment that is designed to be based entirely on computer-generated sensory inputs for one or more senses. A VR environment comprises a plurality of virtual objects with which a person may sense and/or interact. For example, computer-generated imagery of trees, buildings, and avatars representing people are examples of virtual objects. A person may sense and/or interact with virtual objects in the VR environment through a simulation of the person's presence within the computer-generated environment, and/or through a simulation of a subset of the person's physical movements within the computer-generated environment.

In contrast to a VR environment, which is designed to be based entirely on computer-generated sensory inputs, a mixed reality (MR) environment refers to a simulated environment that is designed to incorporate sensory inputs from the physical environment, or a representation thereof, in addition to including computer-generated sensory inputs (e.g., virtual objects). On a virtuality continuum, a mixed reality environment is anywhere between, but not including, a wholly physical environment at one end and virtual reality environment at the other end.

In some MR environments, computer-generated sensory inputs may respond to changes in sensory inputs from the physical environment. Also, some electronic systems for presenting an MR environment may track location and/or orientation with respect to the physical environment to enable virtual objects to interact with real objects (that is, physical articles from the physical environment or representations thereof). For example, a system may account for movements so that a virtual tree appears stationary with respect to the physical ground.

Examples of mixed realities include augmented reality and augmented virtuality.

An augmented reality (AR) environment refers to a simulated environment in which one or more virtual objects are superimposed over a physical environment, or a representation thereof. For example, an electronic system for presenting an AR environment may have a transparent or translucent display through which a person may directly view the physical environment. The system may be configured to present virtual objects on the transparent or translucent display, so that a person, using the system, perceives the virtual objects superimposed over the physical environment. Alternatively, a system may have an opaque display and one or more imaging sensors that capture images or video of the physical environment, which are representations of the physical environment. The system composites the images or video with virtual objects, and presents the composition on the opaque display. A person, using the system, indirectly views the physical environment by way of the images or video of the physical environment, and perceives the virtual objects superimposed over the physical environment. As used herein, a video of the physical environment shown on an opaque display is called “pass-through video,” meaning a system uses one or more image sensor(s) to capture images of the physical environment, and uses those images in presenting the AR environment on the opaque display. Further alternatively, a system may have a projection system that projects virtual objects into the physical environment, for example, as a hologram or on a physical surface, so that a person, using the system, perceives the virtual objects superimposed over the physical environment.

An augmented reality environment also refers to a simulated environment in which a representation of a physical environment is transformed by computer-generated sensory information. For example, in providing pass-through video, a system may transform one or more sensor images to impose a select perspective (e.g., viewpoint) different than the perspective captured by the imaging sensors. As another example, a representation of a physical environment may be transformed by graphically modifying (e.g., enlarging) portions thereof, such that the modified portion may be representative but not photorealistic versions of the originally captured images. As a further example, a representation of a physical environment may be transformed by graphically eliminating or obfuscating portions thereof.

An augmented virtuality (AV) environment refers to a simulated environment in which a virtual or computer-generated environment incorporates one or more sensory inputs from the physical environment. The sensory inputs may be representations of one or more characteristics of the physical environment. For example, an AV park may have virtual trees and virtual buildings, but people with faces photorealistically reproduced from images taken of physical people. As another example, a virtual object may adopt a shape or color of a physical article imaged by one or more imaging sensors. As a further example, a virtual object may adopt shadows consistent with the position of the sun in the physical environment.

There are many different types of electronic systems that enable a person to sense and/or interact with various CGR environments. Examples include head-mounted systems, projection-based systems, heads-up displays (HUDs), vehicle windshields having integrated display capability, windows having integrated display capability, displays formed as lenses designed to be placed on a person's eyes (e.g., similar to contact lenses), headphones/earphones, speaker arrays, input systems (e.g., wearable or handheld controllers with or without haptic feedback), smartphones, tablets, and desktop/laptop computers. A head-mounted system may have one or more speaker(s) and an integrated opaque display. Alternatively, a head-mounted system may be configured to accept an external opaque display (e.g., a smartphone). The head-mounted system may incorporate one or more imaging sensors to capture images or video of the physical environment, and/or one or more microphones to capture audio of the physical environment. Rather than an opaque display, a head-mounted system may have a transparent or translucent display. The transparent or translucent display may have a medium through which light representative of images is directed to a person's eyes. The display may utilize digital light projection, OLEDs, LEDs, uLEDs, liquid crystal on silicon, laser scanning light source, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface.

As described above, one aspect of the present technology is the gathering and use of data available from various sources for use during operation of the head-mounted device 100. As an example, such data may identify the user and include user-specific settings or preferences. The present disclosure contemplates that in some instances, this gathered data may include personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, a user profile may be established that stores historical use information that allows the optical module 104 to be adjusted according to the interpupillary distance 210 of one of the users 206. Accordingly, use of such personal information data enhances the user's experience.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of storing a user profile for adjustment of the optical modules 104 according to the interpupillary distance 210 of one of the users 206, the present technology can be configured to allow users to select to “opt in” or “opt out” of participation in the collection of personal information data during registration for services or anytime thereafter. In another example, users can select not to provide data regarding usage of specific applications. In yet another example, users can select to limit the length of time that application usage data is maintained or entirely prohibit the development of an application usage profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, the interpupillary distance 210 of one of the users 206 may be determined each time the head-mounted device 100 is used, such as by using sensors to measure the interpupillary distance 210, and without subsequently storing the information or associating with the particular user.

What is claimed is:

1. A head-mounted device, comprising:
a frame;
an optical module connected to the frame, the optical module configured to display content to a user wearing the head-mounted device;
a control board connected to the frame;
a flexible cable having a first end and a second end, the flexible cable being electrically connected to the control board and to the optical module;
a grounding member that is located on an exterior surface of the flexible cable to direct an electrical charge away from the flexible cable, the optical module, and the control board; and
an antenna configured to receive other signals from a source, the antenna having an antenna grounding path in conductive communication with the grounding member and the frame to direct the electrical charge from the grounding member to the frame through the antenna grounding path.

2. The head-mounted device of claim 1, wherein the grounding member includes a conductive shielding material that is located on the exterior surface of the flexible cable.

3. The head-mounted device of claim 2, wherein the conductive shielding material is further located on an exterior surface of the control board.

4. The head-mounted device of claim 1, wherein the grounding member is in conductive communication with the antenna grounding path through a control board grounding path of the control board.

5. The head-mounted device of claim 1, further comprising:
a grounding clip that secures the antenna to the frame and defines a portion of the antenna grounding path.

6. A head-mounted device, comprising:
a frame;
an optical module connected to the frame, the optical module configured to display content to a user wearing the head-mounted device;
a control board connected to the frame;
a flexible cable having a first end and a second end, the flexible cable being electrically connected to the control board at the first end and electrically connected to the optical module at the second end; and
a grounding tab that is in contact with an exterior surface of the flexible cable adjacent to the first end of the flexible cable, connects the flexible cable to the frame, and defines low impedance path from the exterior surface of the flexible cable to the frame.

7. The head-mounted device of claim 6, wherein the grounding tab includes a collar that extends around the flexible cable to secure the grounding tab to the flexible cable.

8. The head-mounted device of claim 6, wherein:
the flexible cable comprises micro-coaxial cables,
the micro-coaxial cables are arranged laterally adjacent to one another at the first end for connection to the control board, and are arranged laterally adjacent to one another at the second end for connection to the optical module,
the micro-coaxial cables are arranged in a bundle to define a central portion of the flexible cable between the first end and the second end, and
the grounding tab is connected to the flexible cable along the central portion of the flexible cable.

9. The head-mounted device of claim 6, wherein:
the optical module is configured to translate relative to the frame; and
the control board is fixed relative to the frame.

10. A head-mounted device, comprising:
a frame;
an optical module connected to the frame, the optical module configured to display content to a user wearing the head-mounted device;
a control board connected to the frame;
a flexible cable having a first end and a second end, the flexible cable being electrically connected to the control board at the first end and electrically connected to the optical module at the second end;
a conductive gasket in contact with an exterior of the flexible cable adjacent to the first end of the flexible cable to define a first low impedance path from the flexible cable to a grounding path of the control board; and
a grounding member that defines a second low impedance path from the grounding path of the control board to the frame.

11. The head-mounted device of claim 10, wherein the conductive gasket is formed from a compressible material that is compressed between the exterior of the flexible cable and the control board.

12. The head-mounted device of claim 11, wherein the compressible material is a conductive foam.

13. The head-mounted device of claim 10, wherein the grounding member comprises an elongated conductor that is electrically coupled to the grounding path of the control board and to the frame.

14. The head-mounted device of claim 13, wherein the grounding member further comprises a conductive fastener, wherein the elongated conductor is electrically coupled to the grounding path of the control board by the conductive fastener.

15. The head-mounted device of claim 10, further comprising:
a fan configured to circulate air within an interior of the head-mounted device, wherein the grounding member comprises a conductive fastener that is electrically connected to the grounding path of the control board and secures the fan to the frame.

16. The head-mounted device of claim 15, wherein the grounding member is a first grounding member and the conductive fastener is a first conductive fastener, the head-mounted device further comprising:
a second grounding member that defines a third low impedance path from the grounding path of the control board to the frame, wherein the second grounding member further comprises a second conductive fastener that is electrically connected to the grounding path of the control board and an elongated conductor electrically couples the second conductive fastener to the frame.

17. A head-mounted device, comprising:
a frame;
an optical module movably connected to the frame, the optical module configured to display content to a user wearing the head-mounted device, the optical module including an optical module connector;
a control board fixedly connected to the frame, the control board including a control board connector;
a flexible electrical connector electrically coupled to the optical module connector and to the control board connector, the flexible electrical connector configured to transmit a signal between the optical module and the control board; and
a grounding cable configured to direct an electrical charge to the frame, wherein the grounding cable includes a non-insulated conductor that extends along a portion of the flexible electrical connector.

18. The head-mounted device of claim 17, wherein the grounding cable is electrically coupled to the control board connector and to the frame.

19. The head-mounted device of claim 18, wherein:
the flexible electrical connector defines a bend that is configured to route the flexible electrical connector around a component of the head-mounted device that is located between the control board and the optical module, and
the grounding cable extends along the flexible electrical connector from the control board connector and separates from the flexible electrical connector at a location along the flexible electrical connector between the control board connector and the bend.

20. The head-mounted device of claim 18, wherein:
the grounding cable comprises wires,
the control board connector comprises a series of pins,
the flexible electrical connector is electrically connected to a first group of one or more of the pins, and
the wires are electrically connected to a second group of one or more of the pins.

21. The head-mounted device of claim 17, wherein the grounding cable is electrically coupled to the optical module connector and to the frame.

22. The head-mounted device of claim 21, wherein:
the flexible electrical connector defines a bend that is configured to route the flexible electrical connector around a component of the head-mounted device that is located between the control board and the optical module, and
the grounding cable extends along the flexible electrical connector from the optical module connector and separates from the flexible electrical connector at a location along the flexible electrical connector between the bend and the control board connector.

23. The head-mounted device of claim 21, wherein:
the grounding cable comprises wires,
the optical module connector comprises a series of pins,
the flexible electrical connector is electrically connected to a first group of one or more of the pins, and
the wires are electrically connected to a second group of one or more of the pins.
